(19) United States
(12) Patent Application Publication
(10) Pub. No.: US 2005/0082643 A1
(43) Pub. Date: Apr. 21, 2005

(54) Semiconductor element, semiconductor device, method for manufacturing semiconductor element, method for manufacturing semiconductor device, and electronic apparatus

(75) Inventor: Takayuki Kondo, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/931,238

(22) Filed: Sep. 1, 2004

(30) Foreign Application Priority Data
Sep. 11, 2003 (JP) 2003-319984

(51) Int. Cl. H01L 23/544

(52) U.S. Cl. 257/620

(57) ABSTRACT

To provide semiconductor elements, semiconductor devices, methods for manufacturing semiconductor elements, methods for manufacturing semiconductor devices, and electronic apparatuses, when composing a thin film device (a semiconductor device) by attaching a micro tile element onto a substrate, the manufacturing cost can be lowered, the short-circuit of wirings for the thin film device can be reduced or prevented and an increase in the parasitic capacitance can be reduced or prevented. A semiconductor element is formed in a micro tile configuration that is provided by cutting and separating the semiconductor element formed on a semiconductor substrate from the semiconductor substrate. The semiconductor element includes a tile section having a tile configuration, and an insulating layer that is formed on the tile section with an insulating member to insulate the electrode section from a desired member. At least a part of the insulating member protrudes from an outer edge of the tile section.

The present application claims priority to Japanese Patent Application No. 2003-319984 filed Sep. 11, 2003 which is hereby expressly incorporated by reference herein in its entirety.

### BACKGROUND OF THE INVENTION

1. Field of Invention

Exemplary aspects of the present invention relate to semiconductor elements, semiconductor devices, methods for manufacturing semiconductor elements, methods for manufacturing semiconductor devices, and electronic apparatus.

2. Description of Related Art

A related art epitaxial lift-off (ELO) method has been disclosed in which semiconductor elements formed on a substrate are diced into micro tile elements (semiconductor elements), each in the shape of a micro tile configuration, and then separated from the substrate. The micro tile element is handled and attached to an optional substrate (final substrate), thereby forming a substrate equipped with a thin film device. For example, see Japanese Laid-open Patent Application 2000-58562.

### SUMMARY OF THE INVENTION

In the related art, an electrode (terminal) of the micro tile element is connected with an electrical wiring to a terminal of a circuit that is provided on the final substrate. However, for example, when an electrode, provided on an upper surface of the micro tile element that is subject to wiring, has a polarity different from that of the upper surface or a side surface of the micro tile element, the electrical wiring must be formed to cross over the upper surface or the side surface of the micro tile element.

However, when the electrical wiring is formed by aerial wiring, such as wire bonding, the wiring process requires substantial time. In particular, minute wiring is difficult and results in a substantially large manufacturing cost. When the electrical wiring is formed by using a simple method, such as vapor deposition of metal thin films, the electrical wiring may become short-circuited with the side, etc. of the micro tile element. Also, when the side of the micro tile element forms a steep step difference with respect to the substrate surface, there is a possibility that electrical wiring composed of metal thin films may break at the step difference. Furthermore, a parasitic capacitance may be generated between the electrical wiring and the side surface of the micro tile element, such that the semiconductor element cannot be driven at high speeds even though the micro tile element is capable of high-speed operation.

In a method to addresses and/or solve the above and/or other problems, insulation material in a liquid state is coated by an ink jet or a dispenser on an upper surface or a side surface of a micro tile element, which defines a path of the electrical wiring. The insulation material is cured and the electrical wiring is formed on the insulation material. In the process of manufacturing a semiconductor device through forming a micro tile element by the epitaxial lift-off method, and connecting the micro tile element with a final substrate, the steps of wiring and connecting the micro tile element and the final substrate are considered to be indispensable. However, although the steps of coating and curing an insulation material on the path of the electrical wiring may have to be conducted to address and/or solve the above and/or other problems, it is desirous that these steps be omitted, if possible, in view of the manufacturing costs and the like.

Exemplary aspects of the present invention have been made to address the circumstances described above and provide semiconductor elements, semiconductor devices, methods for manufacturing semiconductor elements, methods for manufacturing semiconductor devices, and electronic apparatus, which, when composing a thin film device (a semiconductor device) by attaching a micro tile element onto a substrate, can lower the manufacturing cost, reduce the short-circuit of wirings for the thin film device and reduce an increase in the parasitic capacitance.

To address or achieve the above, a semiconductor element in accordance with an exemplary aspect of the present invention pertains to a semiconductor element in a micro tile configuration that is provided by cutting and separating a semiconductor element formed on a semiconductor substrate from the semiconductor substrate. The semiconductor element includes: a tile section having a tile configuration; an electrode section formed at the tile section; and an insulating section that is formed on the tile section with an insulating member to insulate the electrode from a specified member. At least a part of the insulating member protrudes from an outer edge of the tile section.

In accordance with an exemplary aspect of the present invention, an integrated circuit, or the like, can be formed by connecting a semiconductor element that is formed by cutting and separating the same from a semiconductor substrate to an optional object (final substrate). Furthermore, in the semiconductor element of an exemplary aspect of the present invention, the insulating section protrudes from the outer circumference of the tile section that composes a base material of the semiconductor element, such that, when the semiconductor element is connected to the final substrate, the insulating section (the protruded section in particular) of the semiconductor element is disposed on a circumferential area adjacent to a connection section between the side surface section of the tile section and the surface of the final substrate.

Accordingly, by forming an electrical wiring that connects the electrode section of the semiconductor element and an electrode of the final substrate in a manner to traverse the insulating section, short-circuit of the electrical wiring to the side surface of the tile section and the surface of the final substrate can be avoided.

A cross-sectional configuration in a region where the electrical wiring is formed has a gentle slope or a smooth curve due to the insulating section, such that chances of breakage of the electrical wiring can be substantially reduced. For example, even when the side surface of the tile section traverses the surface of the final substrate at right angles, an area around the side surface is covered by the insulating section. The insulating section provides the surface where the electrical wiring is formed with a smooth curved surface. In accordance with an exemplary aspect of the present invention, when the semiconductor element and the final substrate are connected, an end section (a side surface or the like) of the tile section of the semiconductor element can be automatically covered by the insulating section. As a result, for example, after the semiconductor element is connected to the final substrate, insulation material does not need to be provided around a tangent line between the side surface of the semiconductor element and the surface of the final substrate. Accordingly, while an increase in the number of manufacturing steps can be suppressed, chances of short-circuit of the electrical wiring with the side surface of the tile section or the surface of the final substrate and breakage of the electrical wiring can be reduced.

Furthermore, the tile section of an exemplary aspect of the present invention can be composed of, for example, a tile section 21a and a p-type semiconductor 22, as described below in one of the exemplary embodiments and shown in FIG. 2. The p-type semiconductor 22 may be formed in a columnar configuration and provided near the center of the upper surface of the tile section 21a, and defines a part or all of an electrical functional section to which the electrode section is to be connected.

The insulating section of the semiconductor element of an exemplary aspect of the present invention may be composed of polyimide. Further, the insulating section may have flexibility. By so doing, by attaching (connecting) the semiconductor element to the final substrate through pressing the entirety of the semiconductor element to the final substrate, a portion of the insulating section that protrudes from the circumference of the tile section can bend and adhere to the side surface of the tile section and the surface of the final substrate. Accordingly, the surface defined by the surface of the insulating section where the electrical wiring is formed has a much smoother curved surface. Also, the electrode section may also have flexibility. By so doing, the electrode section that is formed on the insulating section can bend according to the curve of the insulating section, such that chances of breakage and short-circuit of the electrical wiring can be reduced while suppressing an increase in the number of manufacturing steps.

In the semiconductor element of an exemplary aspect of the present invention, the electrode may be continuously provided from the tile section to a protruded section in the insulating section that protrudes from an outer circumference of the tile section. In accordance with an exemplary aspect of the present invention, when the semiconductor element is connected to a final substrate, the electrode section of the semiconductor element and an electrode or wiring of the final substrate can be brought close to each other. Consequently, forming the electrical wiring, to connect the electrode section of the semiconductor element and the electrode or wiring of the final substrate, can be simplified and can be made more secure. A part of the electrode section may be made to protrude outside from the protruded section in the insulating section. By so doing, when the semiconductor element is connected to the final substrate, the extended portion of the electrode section can be automatically, electrically connected to the electrode or wiring of the final substrate. Therefore forming the electrical wiring to connect the electrode section of the semiconductor element and the electrode or wiring of the final substrate, can be further simplified and can be made even more secure. Also, according to the semiconductor element of an exemplary aspect of the present invention, when the protruded section in the insulating section is bent, the electrode section on the protruded section may be bent in a generally identical shape of the bend. By so doing, when the semiconductor element is connected to the final substrate, chances of breakage and short-circuit of the electrode section and the electrical wiring can be reduced, even when the insulating section and the electrode section are bent.

A semiconductor device in accordance with an exemplary aspect of the present invention includes the semiconductor element described above. Also, the semiconductor device in accordance with an exemplary aspect of the present invention may include a substrate (a final substrate) to which the semiconductor device described above is connected. The semiconductor element and the substrate may be adhered to each other through adhesive. Also, the electrode section of the semiconductor element may be electrically connected to a wiring section formed on the substrate. In accordance with an exemplary aspect of the present invention, an integrated circuit or the like can be formed by connecting a semiconductor element that is cut and separated in a micro tile configuration to an optional object (final substrate). It is noted here that the semiconductor element may be formed from a compound semiconductor or a siliconsemiconductor. The final substrate to which the semiconductor element is connected may be formed from a silicon semiconductor substrate, a compound semiconductor substrate, or another material.

Accordingly, in accordance with an exemplary aspect of the present invention, a semiconductor element can be formed on a substrate that is composed of material different from that of the semiconductor element. For example, a surface-emitting laser or a photodiode formed from gallium arsenide may be formed on a silicon semiconductor substrate. Moreover, in accordance with an exemplary aspect of the present invention, as the semiconductor element is connected to the final substrate, the end section of the tile section of the semiconductor element can be automatically covered by the insulating section. As a result, while an increase in the number of manufacturing steps can be suppressed, chances of short-circuit of the electrical wiring that connects the semiconductor element and the final substrate with the side surface of the tile section and the surface of the final substrate and chances of the breakage of the electrical wiring, can be reduced.

In the semiconductor device of an exemplary aspect of the present invention, the protruded section in the insulating section of the semiconductor element may preferably contact the substrate. According to an exemplary aspect of the present invention, the insulating section of the semiconductor element can adhere to the surface of the substrate (final substrate). After the semiconductor element and the final substrate are connected together, there is no need to provide insulation material around a tangent line between the side surface of the semiconductor element and the surface of the final substrate. As a result, according to an exemplary aspect of the present invention, while an increase in the number of manufacturing steps can be suppressed, chances of short-circuit of the electrical wiring with the side surface of the tile section and the surface of the final substrate and chances of the breakage of the electrical wiring, can be reduced. Also, in the semiconductor device in accordance with an exemplary aspect of the present invention, a part of the electrode section that is a part of a section protruding outside from the protruded section in the insulating section may contact the substrate. As a result, by connecting the semiconductor element and the final substrate, a desired electrode section of the semiconductor element can be automatically, electrically connected to a desired electrode of the final substrate, such that chances of short-circuit and breakage of wirings can be reduced while lowering the manufacturing cost.

A method for manufacturing a semiconductor element in accordance with an exemplary aspect of the present invention includes forming the above-described semiconductor element on a semiconductor substrate, and cutting and separating the semiconductor element from the semiconductor substrate. According to an exemplary aspect of the present invention, an integrated circuit or the like, can be formed by bonding a semiconductor element that has been cut and separated to a final substrate and then connecting the semiconductor element and the final substrate with electrical wirings. Furthermore, in accordance with an exemplary aspect of the present invention, an insulating section for an electrical wiring to be used for the wiring connection can be formed in advance on a semiconductor substrate that is an original substrate of the semiconductor element. Then, according to an exemplary aspect of the present invention, when the semiconductor element is bonded to the final substrate, the end section (side surface) of the tile section can be automatically covered by the insulating section, such that, for example, after the semiconductor element has been bonded to the final substrate, insulation material does not have to be provided around a tangent line between the side surface of the semiconductor element and the surface of the final substrate.

A method for manufacturing a semiconductor element in accordance with an exemplary aspect of the present invention comprises: forming a sacrificial layer on a semiconductor substrate; forming a functional layer having an electronic function over the sacrificial layer; forming an electrode section and an insulating section as parts of the functional layer; forming a mask in a specified region on an upper surface of the functional layer, then, undercutting a part of the functional layer by etching so that a side section of the insulating section protrudes in air; and then, cutting and separating a portion of the functional layer, having the insulating section, from the substrate by etching the sacrificial layer, to thereby form a semiconductor element. In accordance with an exemplary aspect of the present invention, only by devising the shape of masks in the related art epitaxial lift-off (ELO) method, a method is provided to automatically cover an end section of the tile section by the insulating section when the semiconductor element is bonded to the final substrate. Accordingly, while an increase in the number of manufacturing steps can be suppressed, chances of short-circuit of the electrical wiring with the side surface of the tile section or the surface of the final substrate and breakage of the electrical wiring can be reduced.

Also, the method for manufacturing a semiconductor element in accordance with an exemplary aspect of the present invention, the etching may be isotropic etching. By this, an undercut of the insulating section in the functional layer can be readily formed. The mask may be formed such that one edge of the mask matches with an end of the side section of the insulating section. Moreover, the mask may be formed to cover a specified functional region in the functional layer, and to protrude from sections other than a side section of the insulating section in an edge section of the functional region. The mask may be formed with a resist mask. By so doing, a part of the functional layer can be readily undercut by etching so that, while regions other than the insulating section in the functional layer remain, the side section of the insulating section can be protruded in the air.

A method for manufacturing a semiconductor device in accordance with an exemplary aspect of the present invention is characterized in bonding a semiconductor element manufactured by using the method for manufacturing a semiconductor element described above to a final substrate, that is a substrate different from the semiconductor substrate cut and separated, such that the insulating section covers an end section of the tile section. According to an exemplary aspect of the present invention, by bonding the semiconductor element to the final substrate, the insulating section of the semiconductor element can automatically cover the end section of the tile section. As a result, insulation material does not need to be provided around a tangent line between the side surface of the semiconductor element and the surface of the final substrate, after the semiconductor element is bonded to the final substrate. Accordingly, in accordance with an exemplary aspect of the present invention, while an increase in the number of manufacturing steps can be suppressed, chances of short-circuit of the electrical wiring with the side surface of the tile section or the surface of the final substrate and breakage of the electrical wiring can be reduced. Moreover, in the method for manufacturing a semiconductor device in accordance with an exemplary aspect of the present invention is characterized in that, as the semiconductor element is bonded to the final substrate, the electrode section and a wiring section formed on the final substrate may be electrically connected to one another. According to an exemplary aspect of the present invention, forming the electrical wiring to connect the electrode section of the semiconductor element and the electrode or wiring of the final substrate can be simplified and can be made more secure.

An electronic apparatus in accordance with an exemplary aspect of the present invention is includes the semiconductor device described above. According to an exemplary aspect of the present invention, an electronic apparatus equipped with a semiconductor device formed by using an epitaxial lift-off (ELO) method can be provided at a low cost as an equipment with which the number of occurrences in short-circuit problems and wiring breakage problems is low.

### BRIEF DESCRIPTION OF THE DRAWINGS

FIG. 1 is a schematic illustrating a method for manufacturing a semiconductor element in accordance with an exemplary embodiment of the present invention;

FIG. 2 is a schematic illustrating a semiconductor element in accordance with an exemplary embodiment of the present invention;

FIG. 3 is a schematic illustrating a method for manufacturing a semiconductor device in accordance with an exemplary embodiment of the present invention;

FIG. 4 is a schematic illustrating a semiconductor device in accordance with an exemplary embodiment of the present invention;

FIG. 5 is a schematic illustrating a semiconductor element in accordance with another exemplary embodiment of the present invention;

FIG. 6 is a schematic illustrating a semiconductor device in accordance with another exemplary embodiment of the present invention;

FIG. 7 is a schematic illustrating a semiconductor device in accordance with another exemplary embodiment of the present invention;

FIG. 8 is a schematic illustrating the first step of an exemplary method for manufacturing a semiconductor element in accordance with an exemplary embodiment of the present invention;

FIG. 9 is a schematic illustrating the second step of an exemplary manufacturing method;

FIG. 10 is a schematic illustrating the third step of an exemplary manufacturing method;

FIG. 11 is a schematic illustrating the fourth step of an exemplary manufacturing method;

FIG. 12 is a schematic illustrating the fifth step of an exemplary manufacturing method;

FIG. 13 is a schematic illustrating the sixth step of an exemplary manufacturing method;

FIG. 14 is a schematic illustrating the first step of an exemplary method for manufacturing a semiconductor device in accordance with an exemplary embodiment of the present invention;

FIG. 15 is a schematic illustrating the second step of an exemplary manufacturing method;

FIG. 16 is a schematic illustrating the third step of an exemplary manufacturing method;

FIG. 17 is a schematic illustrating the fifth step of an exemplary manufacturing method;

FIGS. 18(a)-(c) are schematics illustrating examples of an electronic apparatus equipped with a semiconductor device of an exemplary aspect of the present invention; and

FIG. 19 is a schematic illustrating another example of an electronic apparatus equipped with semiconductor devices of an exemplary aspect of the present invention.

### DETAILED DESCRIPTION OF EXEMPLARY EMBODIMENTS

Semiconductor Element and its Manufacturing Method

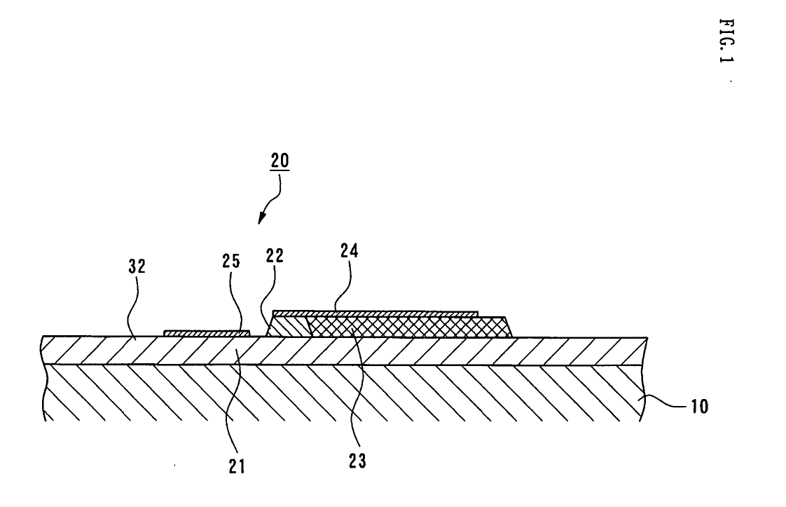

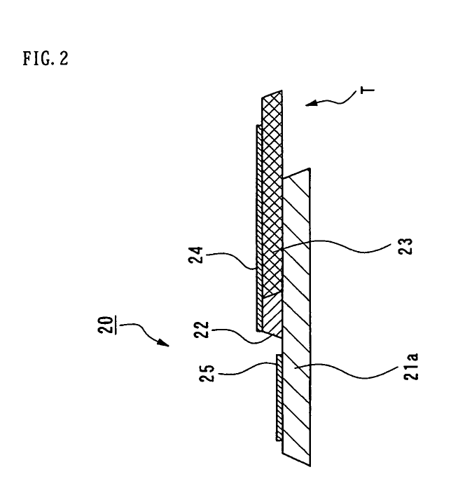

A semiconductor element (thin film device) and its manufacturing method in accordance with an exemplary aspect of the present invention will be described below. FIG. 1 and FIG. 2 are schematics of main portions showing a method for manufacturing a semiconductor element in accordance with an exemplary aspect of the present invention. Also, FIG. 2 is a schematic of a semiconductor element in accordance with an exemplary aspect of the present invention.

The method for manufacturing a semiconductor element in accordance with an exemplary embodiment of the present invention uses an epitaxial lift-off (ELO) method in which, a sacrificial layer is formed on a semiconductor substrate. A functional layer is deposited on an upper layer of the semiconductor substrate to thereby form a semiconductor device. The sacrificial layer is etched to thereby cut and separate the semiconductor element from the semiconductor substrate. FIG. 1 shows the state in which a semiconductor element 20 is formed on a substrate (semiconductor substrate) 10. A sacrificial layer is disposed between the substrate 10 and the semiconductor device 20, specifically, between the substrate 10 and an n-type semiconductor 21, although it is not shown in the figure.

The substrate 10 is a semiconductor substrate, and may be for example, a gallium arsenide compound semiconductor substrate. The present exemplary embodiment is described, as an example, as having a surface-emitting laser (VCSEL: vertical-cavity surface-emitting laser) as the semiconductor element 20. However, the present invention is not limited to this exemplary embodiment. Exemplary aspects of the present invention can be applied to the substrate 10 that has a specified electrode section and an insulating section that insulates the electrode section from other members.

The semiconductor element 20 is equipped with an n-type semiconductor 21, an active layer (not shown in the figure), a p-type semiconductor 22, an insulating layer (insulating section) 23, an anode electrode (electrode section) 24, and a cathode electrode 25. The n-type semiconductor 21 is formed on an upper layer of the sacrificial layer provided on an upper layer of the substrate 10.

Moreover, the n-type semiconductor 21 composes a DBR (Distributed Bragg Reflector) mirror composed of n-type AlGaAs multilayer films, for example. The active layer is stacked on the n-type semiconductor 21. When a micro tile element is formed (see FIG. 2), the active layer is deposited in a thin columnar configuration in a region near the center of an upper surface of a micro tile configuration (corresponding to the tile section 21a in FIG. 2) defined by the n-type semiconductor 21, and may be composed of AlGaAs, for example. The p-type semiconductor 22 is stacked on an upper surface of the active layer in a columnar configuration, and composes a DBR mirror composed of p-type AlGaAs multilayer films, for example. An optical resonator which is a surface-emitting laser is formed with the n-type semiconductor 21, the active layer, and the p-type semiconductor 22.

The cathode electrode 25 is provided on the n-type semiconductor 21. Specifically, the cathode electrode 25 is provided on regions other than the region of the upper surface of the n-type semiconductor 21 where the above-described active layer and the p-type semiconductor 22 are formed. Specifically, on regions other than the central area in the upper surface of the n-type semiconductor 21. The cathode electrode 25 ohmically contacts the n-type semiconductor 21.

The configuration and placement of the insulating layer 23 are one of the characteristics of an exemplary aspect of the present invention. The insulating layer 23 is provided on an upper surface of the n-type semiconductor 21, and reduces the likelihood or prevents the anode electrode 24 side from being short-circuited with the n-type semiconductor 21 side. The insulating layer 23 is formed to have a relatively larger size in advance such that, when a micro tile element is formed by cutting the semiconductor element 20 in a micro tile configuration and separating the same from the substrate 10 (see FIG. 2), at least a part of the insulating layer 23 protrudes from the outer edge of the main body of the tile section (the tile section 21a in FIG. 2 composed of the n-type semiconductor 21). It is noted here that the disposition of the insulating layer 23 may be arranged so that at least a part of the insulating layer 23 protrudes from the outer edge of the tile section 21a, as described above.

The insulating layer 23 is formed with polyimide, for example. Also, the insulating layer 23 may have flexibility. Specifically, it is desirable that the insulating layer 23 can be readily bent as a single member, and does not have cracks, even when it is bent. Therefore, as long as the conditions described above are met, the insulating layer 23 may be composed of resin, glass, ceramic or silicon oxide (SiO₂), and the like, for example.

The anode electrode 24 is provided in a manner to cover the upper surface of the p-type semiconductor 22 and the upper surface of the insulating layer 23 with a single metal film. The anode electrode 24 ohmically contacts the p-type semiconductor 22. Also, the anode electrode 24 may have flexibility. It is desirable that the anode electrode 24 and the insulating layer 23 are formed such that, when the insulating layer 23 is bent by an external force, etc., the anode electrode 24 can also bend while sticking to the insulating layer 23 (that is, in the same shape as that of the insulating layer 23).

After the semiconductor element 20 is formed on the substrate 10 as described above, the sacrificial layer disposed between the substrate 10 and the semiconductor element 20 is etched. As a result, the semiconductor element 20 in a micro tile configuration shown in FIG. 2 is separated from substrate 10. The semiconductor element 20 may be separated from the substrate 10 by a technique other than the method of etching the sacrificial layer. The semiconductor element 20 shown in FIG. 2 is a plate-like member having a thickness of 20⁻⁴ m or less, and a size in length and width ranging from several ten⁻⁴m to hundred⁻⁴m, for example. Moreover, the semiconductor element 20 defines a tile section 21a in a micro tile configuration that is formed as a result of the n-type semiconductor 21 being cut by the etching described above.

In addition, the insulating layer (insulating section) 23 is formed to have a protruded section T projecting from the outer edge (upper surface) of the tile section 21a. To form the protruded section T, specifically, an overhang, a resist mask is formed on the semiconductor element 20 in the state of the substrate 10 shown in FIG. 1, and wet etching or the like, is conducted to undercut the insulating layer in order to form the protruded section T. Then, the semiconductor element 20 in the configuration shown in FIG. 2 can be formed by etching the above-described sacrificial layer. The process of manufacturing the semiconductor element 20 is described in detail below.

Semiconductor Device and its Manufacturing Method

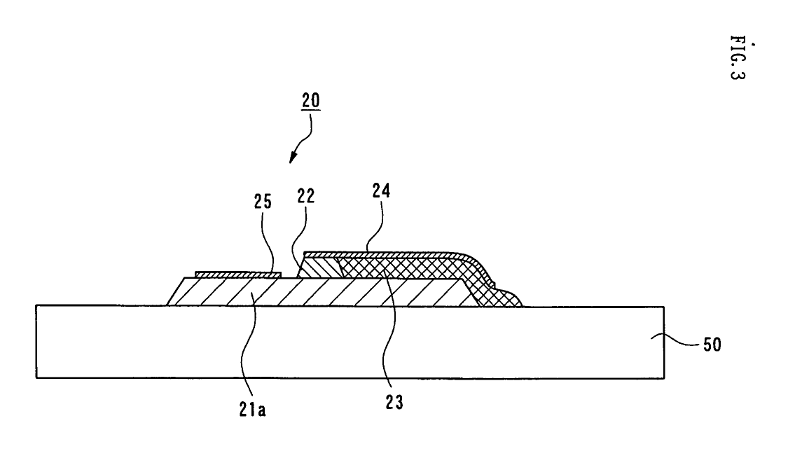

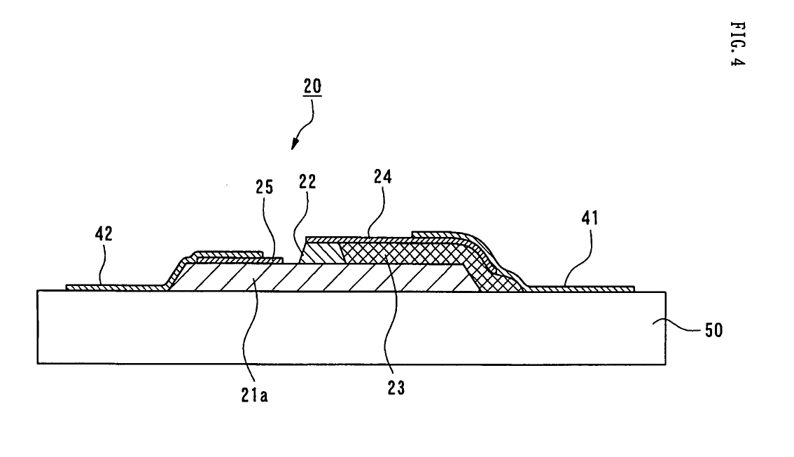

Next, a semiconductor device using a semiconductor element in accordance with an exemplary aspect of the present invention and its manufacturing method is described. FIG. 3 and FIG. 4 are schematics of main portions schematically showing a method for manufacturing a semiconductor device using a semiconductor element in accordance with an exemplary aspect of the present invention. Also, FIG. 4 is a schematic of a semiconductor device in accordance with an exemplary aspect of the present invention. First, the semiconductor element 20 formed as shown in FIG. 2 is connected to a final substrate 50. The final substrate 50 is not particularly limited as long as it is formed from material different from that of the substrate 10. For example, any optional material, such as silicon, ceramic, glass, glass epoxy, plastic, polyimide or the like can be applied as the final substrate 50. It is assumed that an electronic device, an electro-optical device, electrodes, an integrated circuit (not shown in the figure), etc. may be provided on the final substrate 50.

The semiconductor element 20 and the final substrate 50 may be connected together by, for example, adhesive, through adhering the bottom of the semiconductor element 20 and the surface of the final substrate 50. In this bonding, it is desirable that a side section of the insulating layer 23 in the semiconductor element 20, that is, the protruded section T, comes in contact with the surface of the final substrate 50. Specifically, the semiconductor element 20 is bonded to the final substrate 50 in a manner that the protruded section T of the insulating layer 23 of the semiconductor device 20 shown in FIG. 2 is bent downward. The protruded section T is made to adhere to the side surface of the tile section 21a. As a result, when the semiconductor element 20 is bonded to the final substrate 50, the insulating layer 23 of the semiconductor element 20 automatically adheres to the surface of the final substrate 50 and the side surface of the tile section 21a, and the insulating layer 23 automatically covers the end section of the tile section 21a. In addition, the insulating layer 23 is disposed on a path of an electrical wiring that electrically connects the semiconductor element 20 and the final substrate 50.

Next, the semiconductor element 20 and the final substrate 50 are electrically connected as shown in FIG. 4. Specifically, an electrical wiring 41, that electrically connects the anode electrode 24 of the semiconductor element 20 and an electrode (not shown in the figure) on the final substrate 50, is provided. Also, an electrical wiring 42, that electrically connects the cathode electrode 25 of the semiconductor element 20 and an electrode on the final substrate 50, is provided. It is noted here that the electrical wiring 41 is formed to traverse the upper surface of the insulating layer 23 of the semiconductor element 20. As a result, a semiconductor device in accordance with an exemplary aspect of the present invention, having the semiconductor element 20 as its component, is completed.

According to the method for manufacturing the semiconductor device in accordance with the present exemplary embodiment, the insulating layer 23 can reduce the likelihood or prevent the electrical wiring 41 from coming in contact and becoming short-circuited with the tile section 21a. The insulating layer 23 can provide the step difference in the path of the electrical wiring 41 (i.e., the step difference formed by a side surface section of the tile section 21a on the surface of the final substrate 50) with a smooth curved surface, which can reduce the likelihood or prevent the electrical wiring 41 from breaking. In accordance with the present exemplary embodiment, the end section of the tile section 21a can be covered by the insulating layer 23 only by bonding the semiconductor element 20 to the final substrate 50. Consequently, in accordance with the present exemplary embodiment, chances of short-circuit and breakage of the electrical wiring 41 can be reduced or prevented without providing insulation material around a tangent line between the side surface of the semiconductor element 20 and the surface of the final substrate 50 after the semiconductor element 20 is bonded to the final substrate 50. Moreover, according to the present exemplary embodiment, because the separation between the electrical wiring 41 and the side surface of the tile section 21a (n-type semiconductor) can be readily enlarged by the insulating layer 23, the parasitic capacitance generated between sides of the electrical wiring 41 and tile section 21a can be readily reduced.

Consequently, in accordance with the present exemplary embodiment, the electrical wiring 41, which connects the electrode on the upper surface of the semiconductor element 20 that is a micro tile element to the electrode on the final substrate 50, can be readily formed two-dimensionally without providing an aerial wiring, such as wire bonding. Therefore, a thin film device that is smaller and has a lower probability of occurrences of short-circuit and breakage of wirings compared to the related art device, and operates at high speed can be readily composed.

Other Semiconductor Elements And Devices

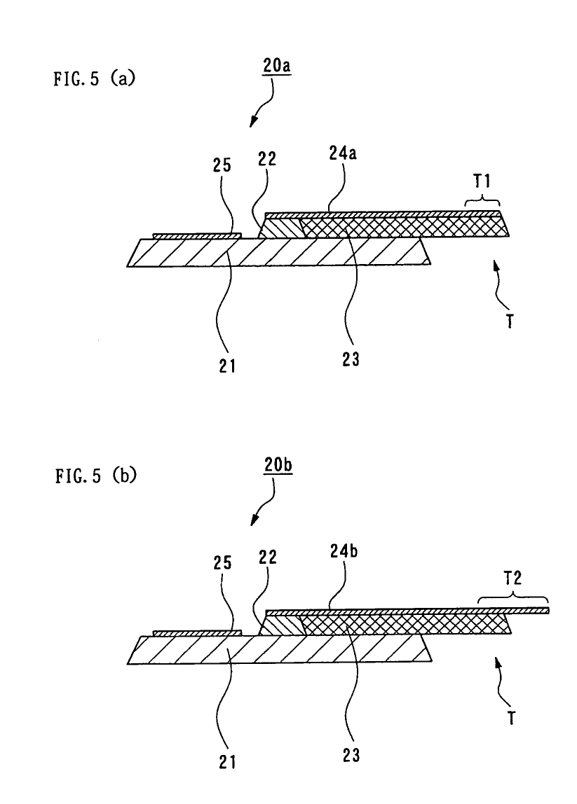

Next, another semiconductor element in accordance with an exemplary aspect of the present invention is described with reference to FIGS. 5(a)-(b). FIGS. 5(a)-(b) are schematics illustrating another semiconductor element in accordance with an exemplary aspect of the present invention. FIG. 5(a) shows a semiconductor element 20a which is a variation of the semiconductor element 20 shown in FIG. 2, and that can be manufactured by using the manufacturing method described with reference to FIG. 1 and FIG. 2 above. The difference between the semiconductor element 20a and the semiconductor element 20 resides in an anode electrode 24a (electrode section). Specifically, the anode electrode 24a is continuously provided from the upper surface of the p-type semiconductor 22 and the tile section 21a to an end section of the protruded section T of the insulating layer 23. The anode electrode 24a of the semiconductor element 20a is longer by an end section T1 than the anode electrode 24 of the semiconductor element 20 shown in FIG. 2. By forming the anode electrode 24a in advance on the substrate 10 shown in FIG. 1, the semiconductor element 20a can be manufactured in a manner similar to the method for manufacturing the semiconductor element 20.

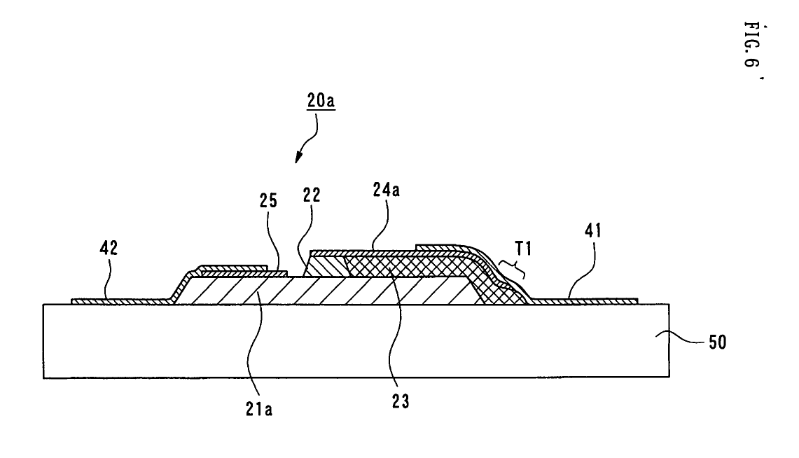

A semiconductor device using the semiconductor element 20a is described with reference to FIG. 6. FIG. 6 is a schematic of a semiconductor device having the semiconductor element 20a of an exemplary aspect of the present invention as its component. The semiconductor device can be manufactured by using the manufacturing method described above with reference to FIG. 3 and FIG. 4. In accordance with the present exemplary embodiment, when the semiconductor element 20a is bonded to the final substrate 50, shown in FIG. 6, the anode electrode 24a of the semiconductor element 20a and an electrode or wiring of the final substrate 50 can be brought close to each other. Accordingly, the process of forming the electrical wiring 41 that connects the anode electrode 24a of the semiconductor element 20a and the electrode or wiring of the final substrate 50 can be simplified and made more secure.

A semiconductor element 20b shown in FIG. 5(b) is also a variation of the semiconductor element 20 shown in FIG. 2, and can be manufactured by using the manufacturing method described above with reference to FIG. 1 and FIG. 2. The difference between the semiconductor element 20b and the semiconductor element 20 also resides in an anode electrode 24b (electrode section). Specifically, the anode electrode 24b is continuously provided from the upper surface of the p-type semiconductor 22 and the tile section 21a to an end section of the protruded section T of the insulating layer 23, and an end of the anode electrode 24b projects outside from the protruded section T of the insulating layer 23. The anode electrode 24b of the semiconductor element 20b is longer by an end section T2 than the anode electrode 24 of the semiconductor element 20 shown in FIG. 2. Accordingly, the anode electrode 24b of the semiconductor element 20b is longer than the anode electrode 24b of the semiconductor element 20a. By forming the anode electrode 24b in advance on the substrate 10 shown in FIG. 1, the semiconductor element 20b can be manufactured in a manner similar to the manufacturing method for the semiconductor element 20.

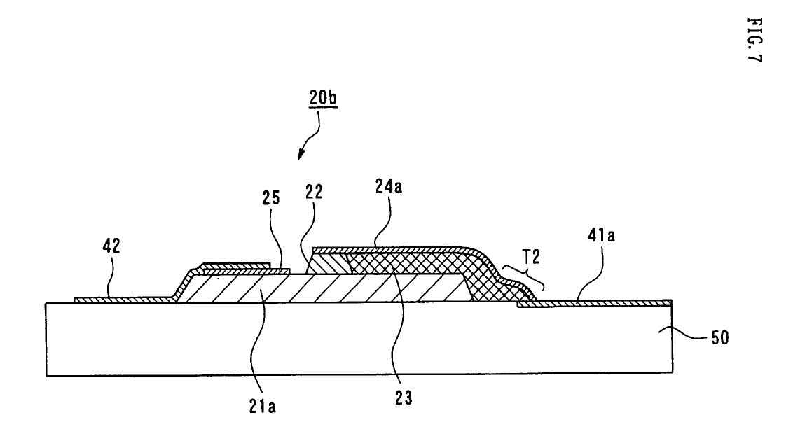

A semiconductor device using the semiconductor element 20b will be described with reference to FIG. 7. FIG. 7 is a schematic of a semiconductor device having the semiconductor element 20b of an exemplary aspect of the present invention as its component. The semiconductor device can be manufactured by using the manufacturing method described above with reference to FIG. 3 and FIG. 4. In accordance with the present exemplary embodiment, an electrical wiring 41a may be formed in advance on a surface of a final substrate 50. When the semiconductor element 20b is bonded to the final substrate 50, as shown in FIG. 7, an extended section at the end section T2 of the anode electrode 24b is automatically brought in mechanical and electrical contact with the electrical wiring 41a provided on the surface of the final substrate 50. Accordingly, the process of connecting the anode electrode 24b of the semiconductor element 20b and the electrical wiring 41a of the final substrate 50 can be further simplified and made more secure.

Also, in the semiconductor elements 20, 20a and 20b in accordance with the present exemplary embodiments, when the protruded section T of the insulating layer 23 is bent, the anode electrodes 24, 24a and 24b on the protruded section may also bend in generally the same shape of the aforementioned bend. By so doing, when the semiconductor elements 20, 20a and 20b are bonded to the final substrate 50, respectively, chances of breakage and short-circuit of the anode electrode 24, 24a and 24b can be reduced even if the insulating layer 23, and the anode electrodes 24, 24a and 24b are bent.

Details of Method for Manufacturing Semiconductor Element

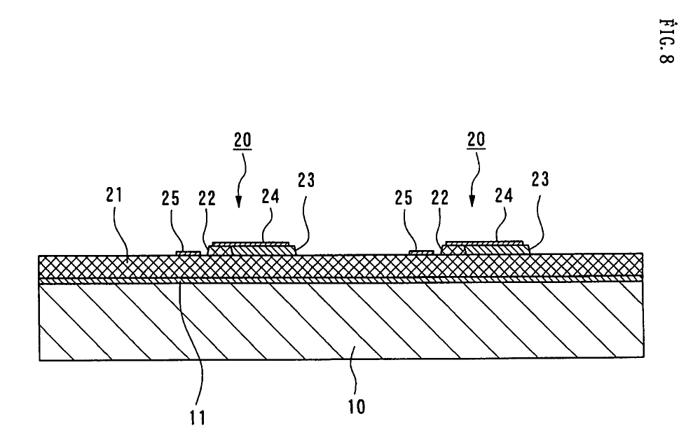

Next, a method for manufacturing the above-described semiconductor element 20 in accordance with an aspect of the present invention is described in details with reference to FIG. 8 through FIG. 13. The present manufacturing method is based on an epitaxial lift-off (ELO) method. Although the present manufacturing method is described for a case where a compound semiconductor device (compound semiconductor element) as a semiconductor element 20 (micro tile element) is bonded on a final substrate, the present manufacturing method is applicable without regard to the kind and configuration of the final substrate. It is noted that the “semiconductor substrate” in the present exemplary embodiment refers to an object that is composed of semiconductor material. However, the “semiconductor substrate” is not limited to a substrate in a plate-shape and may include any semiconductor material in any shape.

First Step

FIG. 8 is a schematic of a first step of the method for manufacturing a semiconductor element 20. In FIG. 8, a substrate 10 corresponds to the substrate 10 shown in FIG. 1, and may be a semiconductor substrate, which is for example a gallium arsenide compound semiconductor substrate. A sacrificial layer 11 is provided as a lowermost layer on the substrate 10. The sacrificial layer 11 includes aluminum arsenide (AlAs), and is a layer having a thickness of, for example, several hundred nm. A functional layer, in which, for example, an n-type semiconductor 21, a p-type semiconductor 22, an insulating layer 23, etc. are formed, is provided on an upper layer of the sacrificial layer 11. The thickness of the functional layer may be about 1⁻⁴ m to about 10 (20)⁻⁴ m. Semiconductor elements (for instance, surface-emitting lasers) 20 are formed in the functional layer.

As the semiconductor element 20, another functional element, such as, for example, a photodiode (PD), or a driver circuit that is composed of a high electron mobility transistor (HEMT), a hetero bipolar transistor (HBT), or the like, an APC circuit, etc. may be formed, besides a surface-emitting laser (VCSEL). Any one of these semiconductor devices 20 is formed by stacking a plurality of epitaxial layers on the substrate 10. Each of the semiconductor devices 20 is formed with an n-type semiconductor 21, an active layer (not shown in the figure), a p-type semiconductor 22, an insulating layer (insulating section) 23, an anode electrode (electrode section) 24, and a cathode electrode 25, as shown in FIG. 1, and is subjected to an operation test. It is noted here that the insulating layer 23 is formed to have a relatively large size in advance so that one end of the insulating layer 23 protrudes from the outer edge of the tile section, as described above with reference to FIG. 1 and FIG. 2.

Second Step

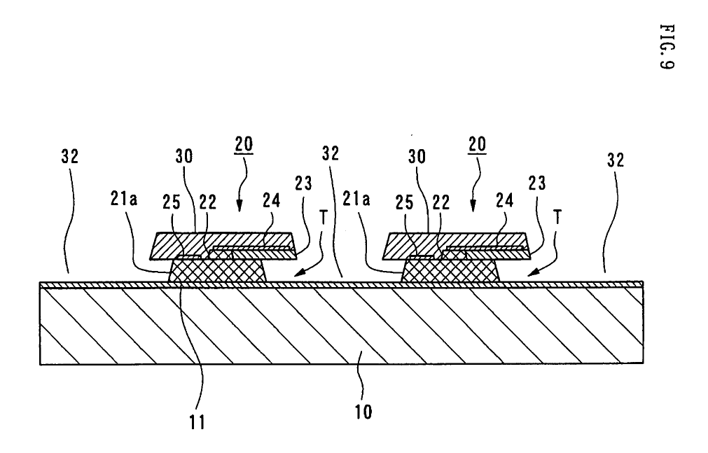

FIG. 9 is a schematic illustrating the second step of the method for manufacturing the semiconductor element 20. In this step, first, a resist mask 30 is formed to cover upper surfaces of the semiconductor elements 20 formed in plurality on the surface layer (functional layer) of the substrate 10. The resist mask 30 is formed in a manner such that one end of the resist mask 30 matches with an end section of the protruded section T of the insulating layer 23 formed in the semiconductor element 20. The resist mask 30 is formed to protrude in areas other than the protruded section T of the insulating layer 23 along the edge sections of the semiconductor element 20, as shown in FIG. 9

Then, isotropic etching, such as wet etching, is conducted on the substrate 10. By so doing, an undercut can be readily made in the insulating layer 23 of the semiconductor element 20, and the protruded section T can be readily formed. Also, the etching depth with respect to the substrate 10 may reach the sacrificial layer 11. By so doing, the etching can form separation grooves 32 that mutually separates the respective semiconductor elements 20 on the substrate 10.

For example, the width and depth of the separation grooves 32 may be 10⁻⁴ m to several hundred⁻⁴ m. The separation grooves 32 may be connected to each other without dead ends so that the selective etching solution to be described below flows through the separation grooves 32. Furthermore, the separation grooves 32 may be formed in a grid-like shape like the one on a chessboard. Further, the interval of the separation grooves 32 may be several ten⁻⁴ m to several hundred⁻⁴ m, such that the size of each of the semiconductor elements 20 separated by the separation grooves 32 may have an area of several ten⁻⁴ m to several hundred⁻⁴ m square. The separation grooves 32 may be formed by a method including photolithography and wet etching, or a dry etching method. The separation grooves 32 may be formed in U-shaped grooves by dicing in a range that does not cause any crack in the substrate.

Third Step

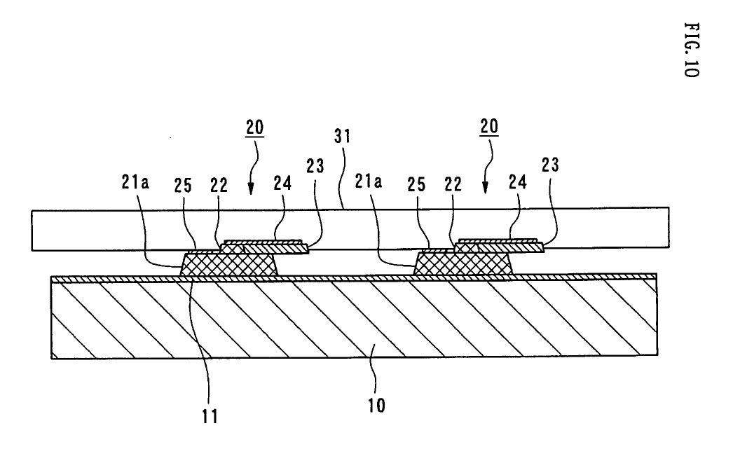

FIG. 10 is a schematic view showing the third step of the method for manufacturing the semiconductor element 20. In this step, an intermediate transfer film 31 is boded to the surface (the upper surface side of the semiconductor element 20) of the substrate 10. The intermediate transfer film 31 is a flexible film having a surface coated with an adhesive. The intermediate transfer film 31 may be formed with PET (polyethylene terephthalate; “T60” made by Toray, 50⁻⁴ m in thickness) as a substrate material, and adhesive formed on the substrate material in a film having a thickness of 30⁻⁴ m to 50⁻⁴ m.

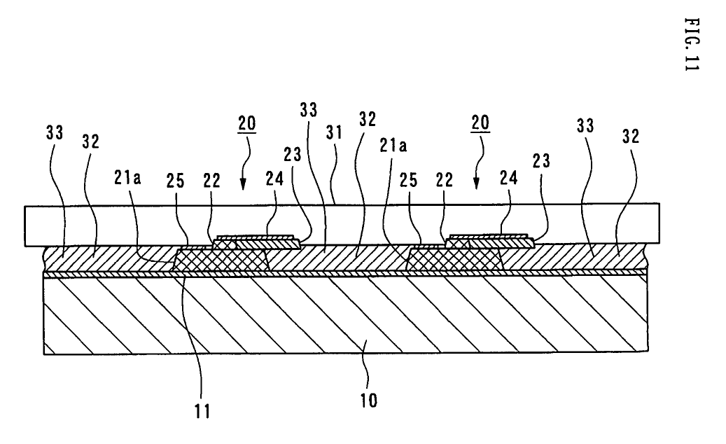

FIG. 11 is a schematic illustrating the fourth step of the method for manufacturing the semiconductor element 20. In this step, a selective etching solution 33 is injected into the separation grooves 32. In this step, low concentration hydrochloric acid having high selectivity to aluminum arsenide is used as the selective etching solution 33 to selectively etch only the sacrificial layer 11.

Fifth Step

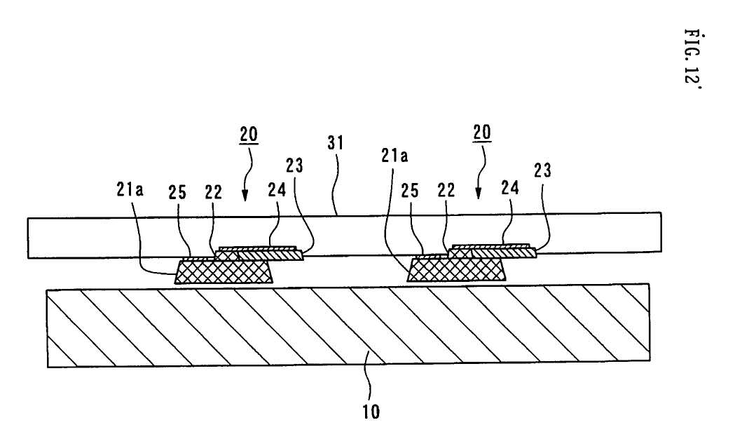

FIG. 12 is a schematic illustrating the fifth step of the method for manufacturing the semiconductor element 20. In this step, the sacrificial layer 11 is entirely removed by selective etching from the substrate 10 after the passage of a predetermined time from the injection of the selective etching solution 33 into the separation grooves 32 in the fourth step.

Sixth Step

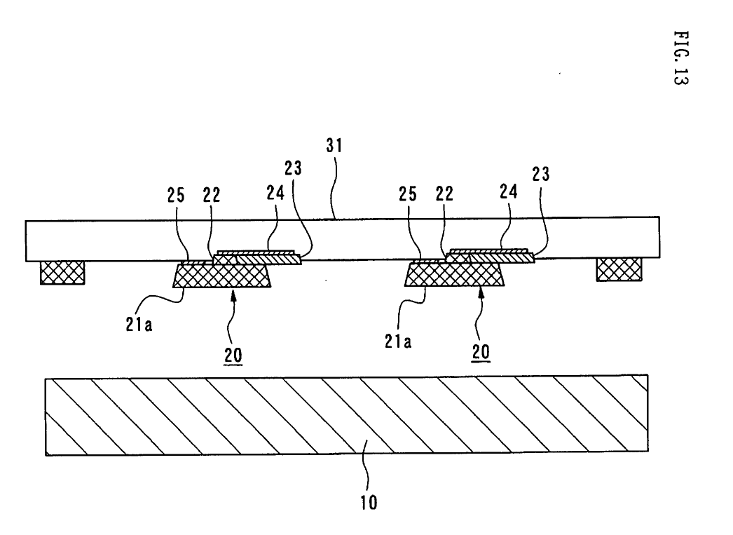

FIG. 13 is a schematic illustrating the sixth step of the method for manufacturing the semiconductor element 20. After the sacrificial layer 11 is entirely etched out in the fifth step, the semiconductor elements 20 (functional layer) are separated from the substrate 10. In this step, the intermediate transfer film 31 is separated from the substrate 10 to separate the semiconductor elements 20 bonded to the intermediate transfer film 31 from the substrate 10. As a result, the functional layer having the semiconductor devices 20 formed thereon is divided into predetermined shapes (for example, micro tile configurations) by the separation grooves 32 formed and the etching of the sacrificial layer 11 to form semiconductor elements 20 shown in FIG. 2, each being adhered to and held by the intermediate transfer film 31. It is noted here that the thickness of the semiconductor element 20 (functional layer) may be, for example, about 1⁻⁴ m to about 10⁻⁴ m, and the size (width and length) may be, for example, several ten⁻⁴ m to several hundred⁻⁴ m.

Details of Method for Manufacturing Semiconductor Device

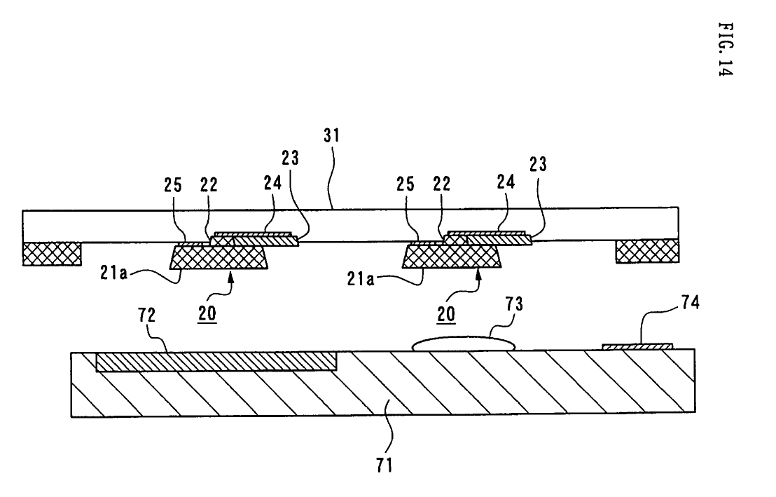

A method for manufacturing a semiconductor device equipped with the semiconductor element 20 in accordance with an exemplary aspect of the present invention thus formed is described in detail below with reference to FIG. 14 through FIG. 17. A description is made below as to an example in which the present manufacturing method is conducted as a post-process that is conducted after the sixth step in the method for manufacturing the semiconductor element described above in detail.

First Step

FIG. 14 is a schematic illustrating the first step of the method for manufacturing the semiconductor device. In this step, the intermediate transfer film 31 (having the semiconductor elements 20 bonded thereto) is moved to align each of the semiconductor elements 20 with a desired position of a final substrate 71 (corresponding to the final substrate 50 in FIG. 3 or FIG. 4). The final substrate 71 is composed of, for example, a silicon semiconductor, and includes a LSI region 72 and an electrode 74 formed thereon. Also, an adhesive 73 is coated on a desired position of the final substrate 71, for bonding the semiconductor element 20. The thickness of the adhesive 73 may be, for example, several⁻⁴ m or less. The adhesive 73 may be coated on the semiconductor element 20.

Second Step

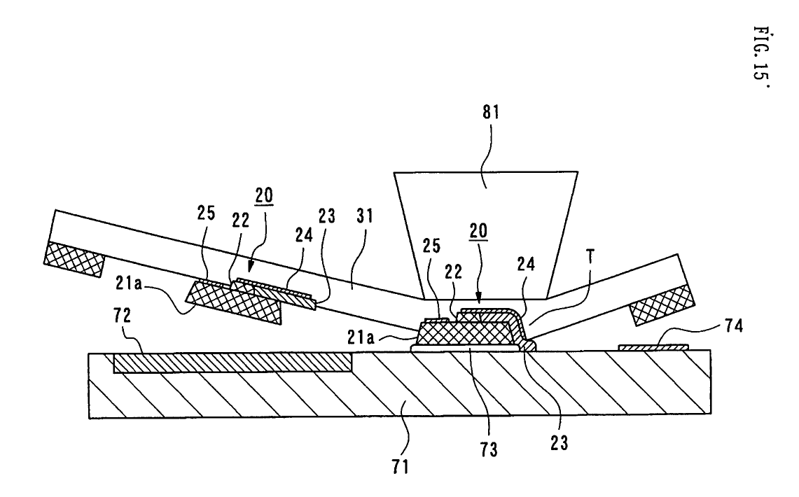

FIG. 15 is a schematic illustrating the second step of the method for manufacturing the semiconductor device. In this step, the semiconductor element 20 aligned with the desired position of the final substrate 71 is pressed by a back pressing pin 81 with the intermediate transfer film 31 provided therebetween, and is joined to the final substrate 71.

When the upper surface of the semiconductor element 20 is pressed by the back pressing pin 81 toward the final substrate 71 with the intermediate transfer film 31 provided therebetween, the protruded section T of the insulating layer 23 is pressed in the direction toward the final substrate 71 and in the direction toward the side surface of the tile section 21a by the intermediate transfer film 31 because the intermediate transfer film 31 has a predetermined thickness and flexibility. By this, the protruded section T of the insulating layer 23 is bent downward and the protruded section T adheres to the side surface of the tile section 21a, the semiconductor element 10 is connected to the final substrate 71. In this manner, by connecting the semiconductor element 20 to the final substrate 71, the insulating layer 23 of the semiconductor element 20 automatically adheres to the adhesive 73 on the surface of the final substrate 71 and the side surface of the tile section 21a, the insulating layer 23 automatically covering the end section of the tile section 21a.

Third Step

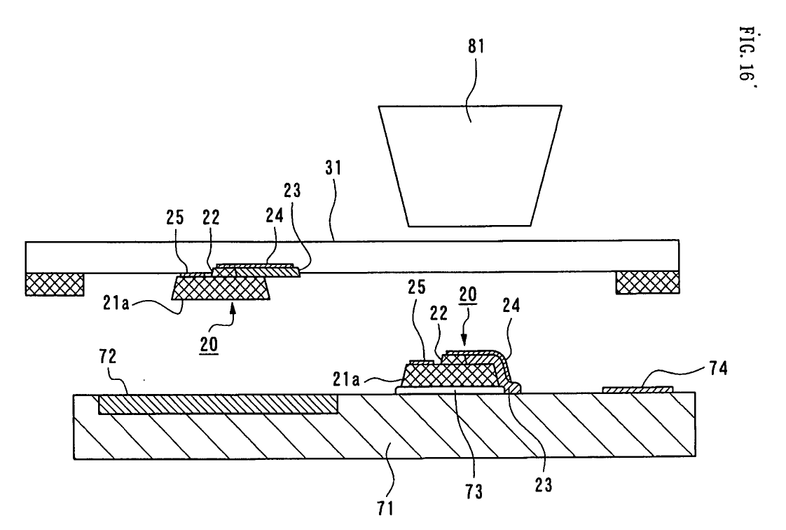

FIG. 16 is a schematic illustrating the third step of the method for manufacturing the semiconductor device. In this step, the adhesive force of the intermediate transfer film 31 is lost to separate the intermediate transfer film 31 from the semiconductor element 20. The adhesive of the intermediate transfer film 31 may be UV settable or heat settable. With the UV settable adhesive, the back pressing pin 81 may be formed from a transparent material, and an ultraviolet ray (UV) is applied through the end of the back pressing pin 81 to lose the adhesive force of the intermediate transfer film 31. With the heat settable adhesive, the back pressing pin 81 may be heated. Alternatively, the entire surface of the intermediate transfer film 31 may be irradiated with an ultraviolet ray to lose the adhesive force of the entire surface after the sixth step in the method for manufacturing the semiconductor element 20. Although the adhesive force is lowered, adhesion actually slightly remains so that the semiconductor element 20 is held on the intermediate transfer film 31 because the semiconductor element 20 is thin and lightweight.

Fourth Step

This step is not illustrated. In this step, the semiconductor element 20 is finally bonded to the final substrate 71 by a heat treatment or the like.

Fifth Step

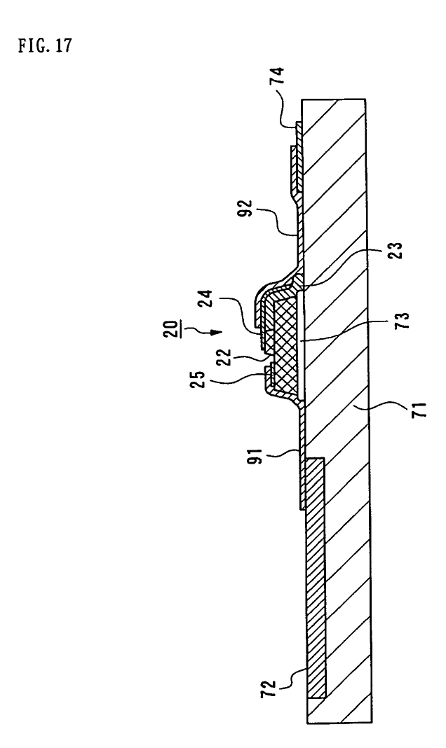

FIG. 17 is a schematic illustrating the fifth step of the method for manufacturing the semiconductor device. In this step, the semiconductor element 20 is electrically connected to the final substrate 71. Specifically, the cathode electrode 25 of the semiconductor element 20 is electrically connected to the LSI region 72 formed on the final substrate 71 through electrical wiring 91. Also, the anode electrode 24 of the semiconductor element 20 is electrically connected to the electrode 74 formed on the final substrate 71 through electrical wiring 92. It is noted here that the electrical wiring 92 is formed to traverse the upper surface of the insulating layer 23 of the semiconductor element 20. The electrical wirings 91 and 92 may be formed by using a droplet discharge method. Liquid containing a desired metal material may be jetted by an ink jet nozzle or a dispenser to desired locations, and hardened to thereby form the electrical wirings 91 and 92. By the steps described above, a semiconductor device in accordance with an exemplary aspect of the present invention, that forms an LSI chip or the like having the semiconductor element 20 as its component, is completed.

Consequently, even when the final substrate 71 is composed of silicon, a semiconductor element 20 equipped with a gallium arsenide surface-emitting laser may be formed at a desired location on the final substrate 71. A semiconductor element, such as a surface-emitting laser can be formed on a substrate composed of a material different from that of the semiconductor element. Furthermore, since a surface-emitting laser or the like can be completed on a semiconductor substrate (the substrate 10) and then separated in a micro tile configuration, the surface-emitting laser or the like can be tested and selected in advance prior to forming an integrated circuit that incorporates the surface-emitting laser. Furthermore, in accordance with the manufacturing method described above, only a functional layer that includes semiconductor elements 20 (surface-emitting lasers or the like) may be cut and separated as micro tile elements from the semiconductor substrate, and mounted on a film for handling. Accordingly, the semiconductor elements 20 can be individually selected and bonded to the final substrate 71, and the size of the semiconductor element 20 that can be handled can be made smaller than the one achieved by the related art mounting technology.

Moreover, in accordance with the manufacturing method described above, only by forming the insulating layer 23 in a desired configuration in the step of forming the semiconductor element 20 on the substrate 10, and transferring the semiconductor element 20 onto the final substrate 71, the insulating layer 23 automatically covers the end section of the tile section 21a of the semiconductor element 20. Consequently, in accordance with the manufacturing method described above, an integrated circuit equipped with a thin film device (semiconductor device) that is compact, has a lower probability of occurrences of short-circuit and breakage of wirings, and operates at a high speed can be readily manufactured at low costs, compared to the related art method.

Electronic Apparatus

Examples of an electronic apparatus including the semiconductor device (thin film device) of any one of the above exemplary embodiments are described below.

The thin film device of any of the above exemplary embodiments is applicable to a surface-emitting laser, a light emitting diode, a photodiode, a phototransistor, a high electron mobility transistor, a hetero bipolar transistor, an inductor, a capacitor or a resistance. As an application circuit or an electrical apparatus equipped with the thin film device, an optical interconnection circuit, an optical fiber communication module, a laser printer, a laser beam projector, a laser beam scanner, a linear encoder, a rotary encoder, a displacement sensor, a pressure sensor, a gas sensor, a blood flow sensor, a fingerprint sensor, a high-speed electromodulation circuit, a wireless RF circuitry, a mobile phone, a wireless LAN, etc. can be enumerated.

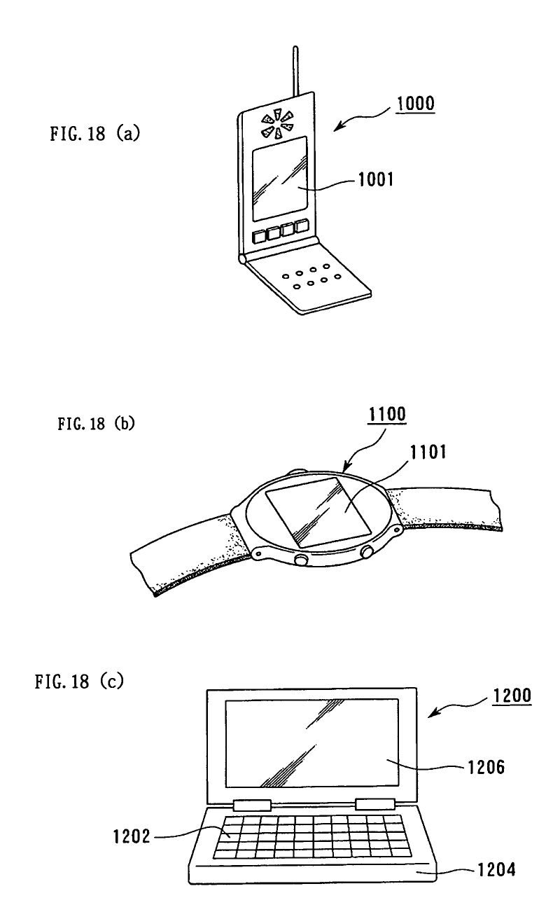

FIG. 18(a) is a schematic showing an example of a cellular phone. In FIG. 18(a), reference numeral 1000 denotes a cellular phone body including the thin film device described above, and reference numeral 1001 denotes a display section. FIG. 18(b) is a schematic showing an example of a wristwatch-type-electronic apparatus. In FIG. 18(b), reference numeral 1100 denotes a watch body including the thin film device described above, and reference numeral 1101 denotes a display section. FIG. 18(c) is a schematic showing an example of portable information processors, such as a word processor, a personal computer, and the like. In FIG. 18(c), reference numeral 1200 denotes an information processor apparatus, reference numeral 1202 denotes an input section, such as a key board or the like, reference numeral 1204 denotes an information processor body using the thin film device described above, and reference numeral 1206 denotes a display section.

Any of the electronic apparatuses shown in FIGS. 18 is equipped with a semiconductor device (thin film device) of any of the exemplary embodiments described above, such that short-circuits are not likely to occur. They can operate at a high speed. They are thin and compact and they can be manufactured at low costs.

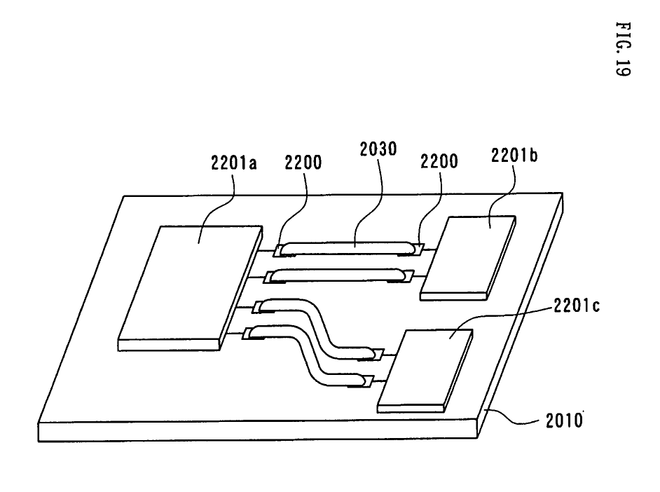

FIG. 19 is a schematic showing an example in which a semiconductor device (thin film device) of any of the exemplary embodiments described above is applied to an inter IC chip optical interconnection circuit apparatus. The inter IC chip optical interconnection circuit apparatus is formed from a substrate 2010, a plurality of integrated circuits 2201a, 2201b and 2201c provided on the substrate 2010, a plurality of micro tile elements 2200 bonded to the substrate 2010, and a plurality of optical waveguides 2030 provided on the substrate 2010. Each of the micro tile elements 2200 corresponds to the semiconductor element 20 in a micro tile configuration (a micro tile element, i.e., a thin film device) shown in FIG. 2 of the exemplary embodiment.

Each of the micro tile elements 2200 may be equipped with a surface-emitting laser or a light receiving element. For example, an electrical signal that is outputted from the integrated circuit 2201a is converted into an optical signal by the micro tile element 2200 located near the integrated circuit 2201a, and is transferred through the optical waveguide 2030. The optical signal may be converted into an electrical signal, for example, by the micro tile element 2200 near the integrated circuit 2201b and inputted in the integrated circuit 2201b. Accordingly, the inter IC chip optical interconnection circuit apparatus of the present exemplary embodiment can send and receive signals at a high speed and perform signal processing at a high speed, is not likely to have wiring short-circuits, is thin and compact, and can be manufactured at low costs.

The technological range of the present invention is not limited to the above-described exemplary embodiments. Various changes can be made within the scope without departing from the subject matter of the present invention. For example, the materials and layer structures of the above exemplary embodiments are only examples, and a proper change can be made.

In the exemplary embodiments described above, a semiconductor element 20 has a structure equipped with a surface-emitting laser. However, the present invention is not limited to these exemplary embodiments. The semiconductor element may include at least one of a light emitting diode, a photodiode, a phototransistor, a high electron mobility transistor, a hetero bipolar transistor, an inductor, a capacitor and a resistance.

Also, in any of the exemplary embodiments described above, the thickness of the insulating layer 23 may be changed according to the rate of frequency of signals input in or output from the semiconductor element 20 (i.e., electrical signals that are transmitted through the electrical wiring 92). For example, when the signals are high frequency signals, such as radio communications signals, the thickness of the insulating layer 23 may be made greater, and the thickness of the insulating layer 23 may be made smaller for relatively low frequencies. As a result, semiconductor devices (thin film devices) equipped with desired electrical characteristics can be readily composed.

1. A semiconductor element in a micro tile configuration that is provided by cutting and separating a semiconductor element formed on a semiconductor substrate from the semiconductor substrate, the semiconductor element comprising:
a tile section having a tile configuration;
an electrode section formed at the tile section; and
an insulating section that is formed on the tile section from an insulating member to insulate the electrode from a specified member, at least a part of the insulating member protruding from an outer edge of the tile section.

2. The semiconductor element according to claim 1, the insulating section having flexibility.

3. The semiconductor element according to claim 1, the insulating section being composed of polyimide.

4. The semiconductor element according to claim 1, the electrode section having flexibility.

5. The semiconductor element according to claim 1, the electrode being continuously provided from the tile section to the protruded section in the insulating section that protrudes from an outer edge of the tile.

6. The semiconductor element according to claim 1, a part of the electrode section protruding outside from the protruded section in the insulating section.

7. The semiconductor element according to claim 1, the protruded section in the insulating section and the electrode section on the protruded section being bent in a generally identical shape.

8. A semiconductor device, comprising:
the semiconductor element according to claim 1.

9. The semiconductor device according to claim 8, the electrode section of the semiconductor element being electrically connected to a wiring section formed on the substrate.

10. The semiconductor device according to claim 8, the protruded section in the insulating section of the semiconductor element contacting the substrate.

11. The semiconductor device according to claim 8, a part of the electrode section that is a part of a section protruding outside from the protruded section in the insulating section contacting the substrate.

12. A method for manufacturing a semiconductor element, forming a semiconductor element according to claim 1 on a semiconductor substrate, and cutting and separating the semiconductor element from the semiconductor substrate.

13. A method for manufacturing a semiconductor element, comprising:
forming a functional layer having an electronic function over a substrate;
forming an electrode section and an insulating section as parts of the functional layer;
forming a mask in a specified region on an upper surface of the functional layer;
then, undercutting a part of the functional layer by etching so that a side section of the insulating section protrudes in air; and
then, cutting and separating a portion of the functional layer having the insulating section from the substrate, to thereby form a semiconductor element.

14. The method for manufacturing a semiconductor element according to claim 13, the etching being isotropic etching.

15. The method for manufacturing a semiconductor element according to claim 13, forming the mask such that one edge of the mask matches with an end of the side section of the insulating section.

16. The method for manufacturing a semiconductor element according to claim 13, forming the mask to cover a specified functional region in the functional layer, and to protrude from sections other than a side section of the insulating section along an edge section of the functional region.

17. A method for manufacturing a semiconductor device, comprising:
bonding a semiconductor element manufactured by using the method for manufacturing a semiconductor element according to claim 12 to a final substrate that is a substrate different from the semiconductor substrate cut and separated, such that the insulating section covers an end section of the tile section.

18. The method for manufacturing a semiconductor device according to claim 17, as the semiconductor element is bonded to the final substrate, the electrode section being electrically connected to a wiring section formed on the final substrate.

19. An electronic apparatus, comprising:
a semiconductor device according to claim 6.
